(19) United States
(12) Patent Application Publication
(10) Pub. No.: US 2015/0123251 A1
(43) Pub. Date: May 7, 2015

(54) SEMICONDUCTOR PACKAGE

(71) Applicant: SILICONWARE PRECISION INDUSTRIES CO., LTD, Taichung (TW)

(72) Inventors: Chih-Hsien Chiu, Taichung (TW); Chia-Yang Chen, Taichung (TW); Tsung-Hsien Tsai, Taichung (TW); Heng-Cheng Chu, Taichung (TW); Cheng-Yu Chiang, Taichung (TW)

(73) Assignee: SILICONWARE PRECISION INDUSTRIES CO., LTD, Taichung (TW)

(21) Appl. No.: 14/133,842

(22) Filed: Dec. 19, 2013

(30) Foreign Application Priority Data
Nov. 6, 2013 (TW) 102140245

(51) Int. Cl. H01L 23/552; H01L 23/31

(52) U.S. Cl. CPC H01L 23/552; H01L 23/31
USPC 257/659

(57) ABSTRACT

A semiconductor package is disclosed, which includes: a packaging structure having at least a semiconductor element; and at least three shielding layers sequentially stacked on the packaging structure so as to cover the semiconductor element, wherein a middle layer of the shielding layers is lower in electrical conductivity than adjacent shielding layers on both sides of the middle layer, thereby reducing electromagnetic interferences so as to increase the shielding effectiveness.

### BACKGROUND OF THE INVENTION

1. Field of the Invention

The present invention relates to semiconductor packages, and more particularly, to a semiconductor package having a shielding structure.

2. Description of Related Art

Currently, electronic products are developed toward the trend of miniaturization and high performance. Particularly, various electronic products, such as cell phones and laptops, are integrated with communication technologies. These electronic products generally comprise RF chips. However, electromagnetic interference (EMI) easily occurs when the RF chips are disposed close to digital IC circuits, digital signal processors (DSPs) or baseband (BB) chips. Therefore, an electromagnetic shielding structure is required.

FIG. 1 is a schematic cross-sectional view of a conventional semiconductor package 1. Referring to FIG. 1, the semiconductor package 1 has a substrate 10, a plurality of chips 11 disposed on the substrate 10, an encapsulant 12 encapsulating the chips 11, and a metal layer 13 covering the encapsulant 12 so as to achieve an EMI-shielding effect.

FIG. 1′ is a partially enlarged view of FIG. 1. Referring to FIG. 1′, when an incident electromagnetic wave W is incident on one side of the metal layer 13 and passes through the metal layer 13, the incident electromagnetic wave W is attenuated such that an electromagnetic wave T is emitted from the other side of the metal layer 13. The shielding effectiveness (SE) shows the level of electromagnetic attenuation by a shield, which is calculated through the following equation:

SE=R+A+B≈R+A

where R represents the reflection loss, A represents the absorption loss and B represents the secondary reflection loss (tiny and negligible). The absorption loss A is calculated as follows:

A=8.69(t/δ)=131.7t\sqrt{fμᵣσᵣ} dB

where t represents the thickness of the shielding layer, i.e., the metal layer 13, f represents the wave frequency, μᵣ represents the relative magnetic permeability and σᵣ represents the electrical conductivity relative to copper.

Therefore, if the material of the shielding layer and the wave frequency are fixed, the absorption loss increases with the thickness of the shielding layer, i.e., the metal layer 13.

However, since the single metal layer 13 is used as the shielding structure of the semiconductor package 1, if the thickness of the metal layer 13 is increased, the overall thickness of the semiconductor package 1 is also increased, thereby hindering the miniaturization of electronic products.

On the other hand, if the wave frequency and the thickness of the metal layer 13 are fixed, a material with a high magnetic permeability and a high electrical conductivity can be used to increase the shielding effectiveness, which however incurs a high cost.

Therefore, there is a need to provide a semiconductor package so as to overcome the above-described drawbacks.

### SUMMARY OF THE INVENTION

In view of the above-described drawbacks, the present invention provides a semiconductor package, which comprises: a packaging structure having at least a semiconductor element; and a shielding structure comprising at least three shielding layers sequentially stacked on the packaging structure so as to cover the semiconductor element, wherein a middle layer of the shielding layers is lower in electrical conductivity than adjacent shielding layers on both sides of the middle layer.

In an embodiment, at least two of the shielding layers are made of different materials.

In an embodiment, the shielding layers are made of materials different from one another.

In an embodiment, at least one of the shielding layers is a conductor layer.

In an embodiment, each of the shielding layers is a conductor layer or a non-conductor layer, and at least one of the shielding layers is a conductor layer.

In an embodiment, an encapsulant is formed on the packaging structure in a manner that the semiconductor element is encapsulated by the encapsulant and the shielding structure is formed on the encapsulant.

In an embodiment, the shielding structure has three, four, five, six or seven shielding layers.

Therefore, the semiconductor package of the present invention attenuates electromagnetic interference through the shielding layers so as to increase the shielding effectiveness.

### BRIEF DESCRIPTION OF DRAWINGS

FIG. 1 is a schematic cross-sectional view of a conventional semiconductor package;

FIG. 1′ is a partially enlarged view of FIG. 1;

FIG. 2 is a schematic cross-sectional view of a semiconductor package of the present invention;

FIG. 2′ is a partially enlarged view of FIG. 2; and

FIGS. 3 to 6 are partially enlarged views showing other embodiments of the semiconductor package of the present invention.

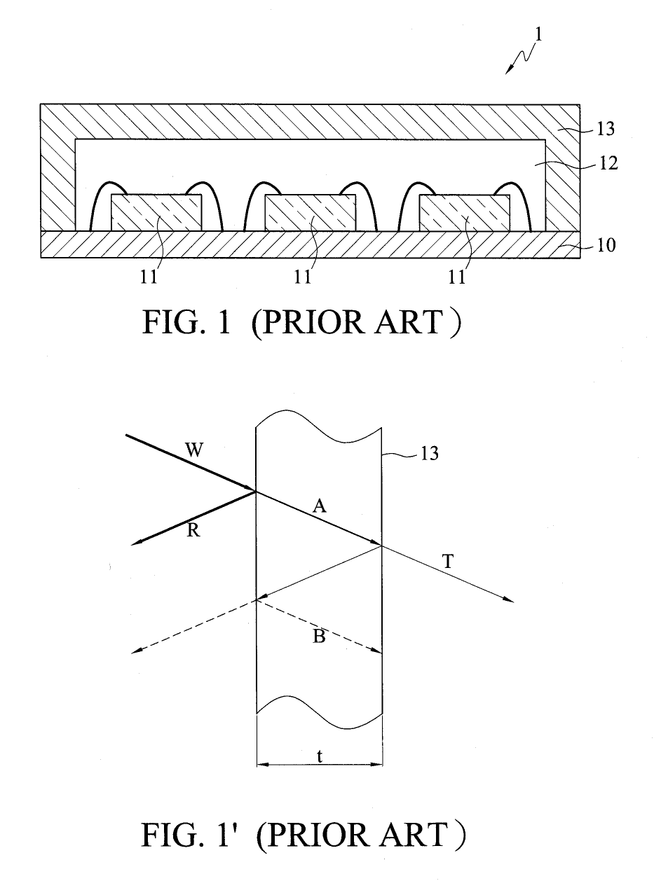

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “outer”, “on”, “a” etc. are merely for illustrative purposes and should not be construed to limit the scope of the present invention.

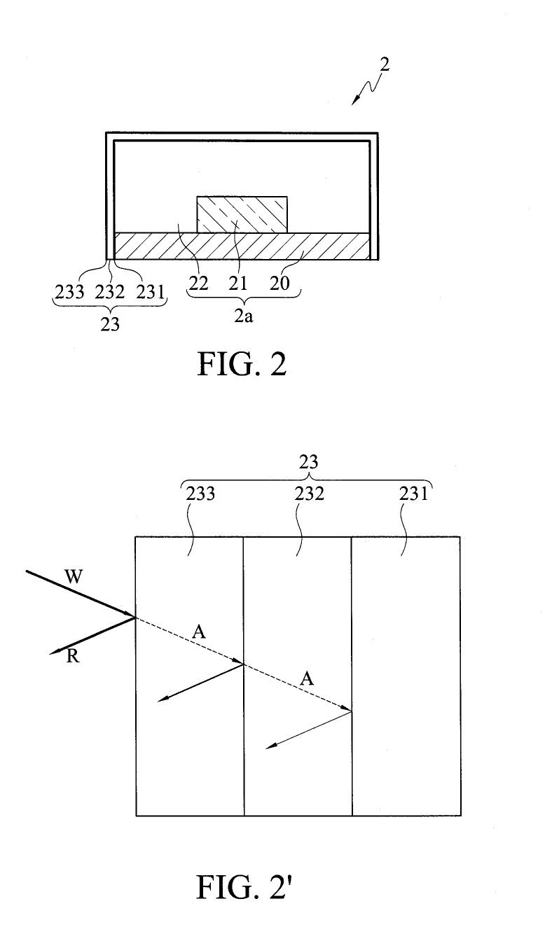

FIG. 2 is a schematic cross-sectional view of a semiconductor package 2 of the present invention. Referring to FIG. 2, the semiconductor package 2 has a packaging structure 2a and a shielding structure 23 disposed on an outer surface of the packaging structure 2a.

The packaging structure 2a has a carrier 20, at least a semiconductor element 21 disposed on the carrier 20, and an encapsulant 22 encapsulating the semiconductor element 21.

The carrier 20 can be, but not limited to, a circuit board or a lead frame.

The semiconductor element 21 can be an active element such as a chip or a passive element. The semiconductor element 21 can be electrically connected to the carrier 20 through flip-chip, wire bonding or other techniques.

The shielding structure 23 has a first shielding layer 231, a second shielding layer 232 and a third shielding layer 233 sequentially stacked on the encapsulant 22. The second shielding layer 232 sandwiched between the first and third shielding layers 231, 233 is lower in electrical conductivity than the first and third shielding layers 231, 233.

In the present embodiment, at least two of the first, second and third shielding layers 231, 232, 233 are made of different materials. In particular, the first, second and third shielding layers 231, 232, 233 are made of materials different from one another.

Each of the first, second and third shielding layers 231, 232, 233 can be a conductor layer or a non-conductor layer, and at least one of the first, second and third shielding layers 231, 232, 233 is a conductor layer.

According to the equation of the shielding effectiveness, the reflection loss is calculated as follows:

$$R = 20 log \frac{\vert {Z}_{w} \vert}{4 \vert {Z}_{s} \vert} dB$$

where Z_{w} represents the wave impedance and Z_{S} represents the shielding impedance.

According to the equation, if Z_{w} is far greater than Z_{S}, the reflection loss R will be large. Therefore, referring to FIG. 2′, the shielding structure 23 made of a plurality of layers of different materials increases the wave impedance and consequently generates a large reflection loss R. Therefore, an incident electromagnetic wave W incident on one side of the shielding structure 23 is greatly attenuated by the shielding structure 23 such that almost no electromagnetic wave is emitted from the other side of the shielding structure 23, thereby increasing the shielding effectiveness.

Further, since the magnetic permeability and electrical conductivity of each of the shielding layers of the shielding structure 23 do not greatly affect the shielding effectiveness, there is a greater freedom on the choice of materials. For example, materials having lower magnetic permeabilities and lower electrical conductivities can be used for the shielding structure 23 so as to reduce the cost.

In addition, since the thickness of the shielding structure 23 does not greatly affect the shielding effectiveness, it can be changed according to the practical need. For example, to achieve the same shielding effect as the prior art, the thickness of the shielding structure 23 can be far less than the thickness of the conventional metal layer. Therefore, the semiconductor package of the present invention not only achieves a desired shielding effect but also meets the miniaturization requirement.

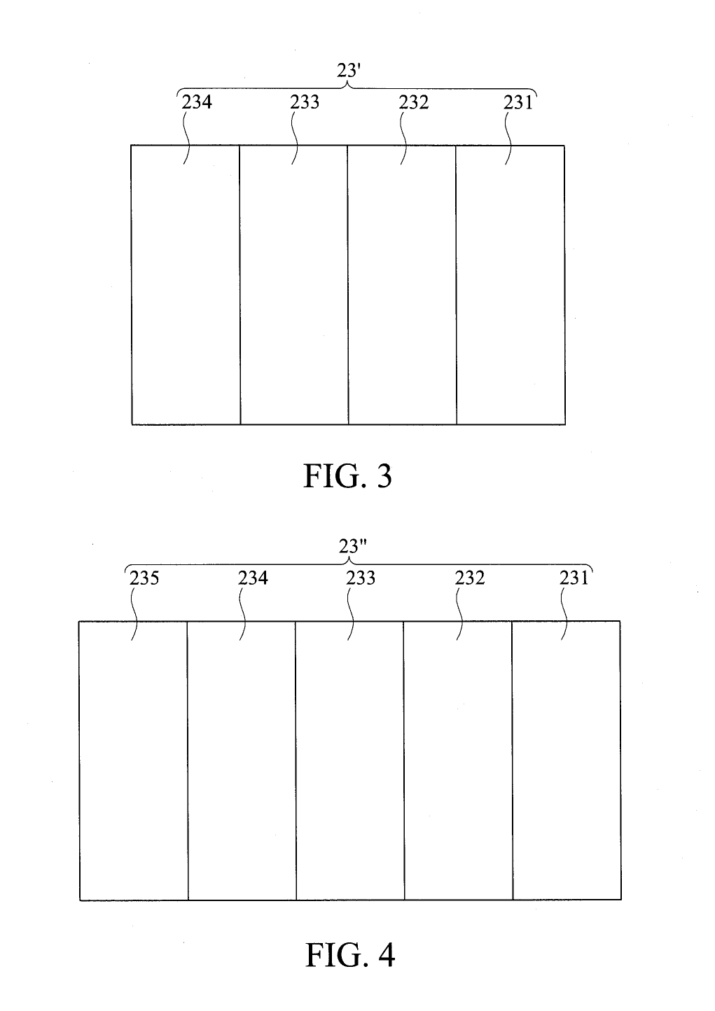

In another embodiment, referring to FIG. 3, the shielding structure 23′ further has a fourth shielding layer 234. The fourth shielding layer 234 can be a conductor layer or a non-conductor layer, and at least one of the first to fourth shielding layers 231 to 234 is a conductor layer.

Further, a middle layer of the shielding layers is lower in electrical conductivity than adjacent shielding layers on both sides of the middle layer. For example, the second shielding layer 232 sandwiched between the first and third shielding layers 231, 233 is lower in electrical conductivity than the first and third shielding layers 231, 233. Alternatively, the third shielding layer 233 sandwiched between the second and fourth shielding layers 232, 234 is lower in electrical conductivity than the second and fourth shielding layers 232, 234.

In another embodiment, referring to FIG. 4, the shielding structure 23″ further has a fifth shielding layer 235. The fifth shielding layer 235 can be a conductor layer or a non-conductor layer, and at least one of the first to fifth shielding layers 231 to 235 is a conductor layer.

In the present embodiment, the second shielding layer 232 sandwiched between the first and third shielding layers 231, 233 is lower in electrical conductivity than the first and third shielding layers 231, 233, or the third shielding layer 233 sandwiched between the second and fourth shielding layers 232, 234 is lower in electrical conductivity than the second and fourth shielding layers 232, 234, or the fourth shielding layer 234 sandwiched between the third and fifth shielding layers 233, 235 is lower in electrical conductivity than the third and fifth shielding layers 233, 235.

In another embodiment, the second shielding layer 232 sandwiched between the first and third shielding layers 231, 233 is lower in electrical conductivity than the first and third shielding layers 231, 233, and the fourth shielding layer 234 sandwiched between the third and fifth shielding layers 233, 235 is lower in electrical conductivity than the third and fifth shielding layers 233, 235.

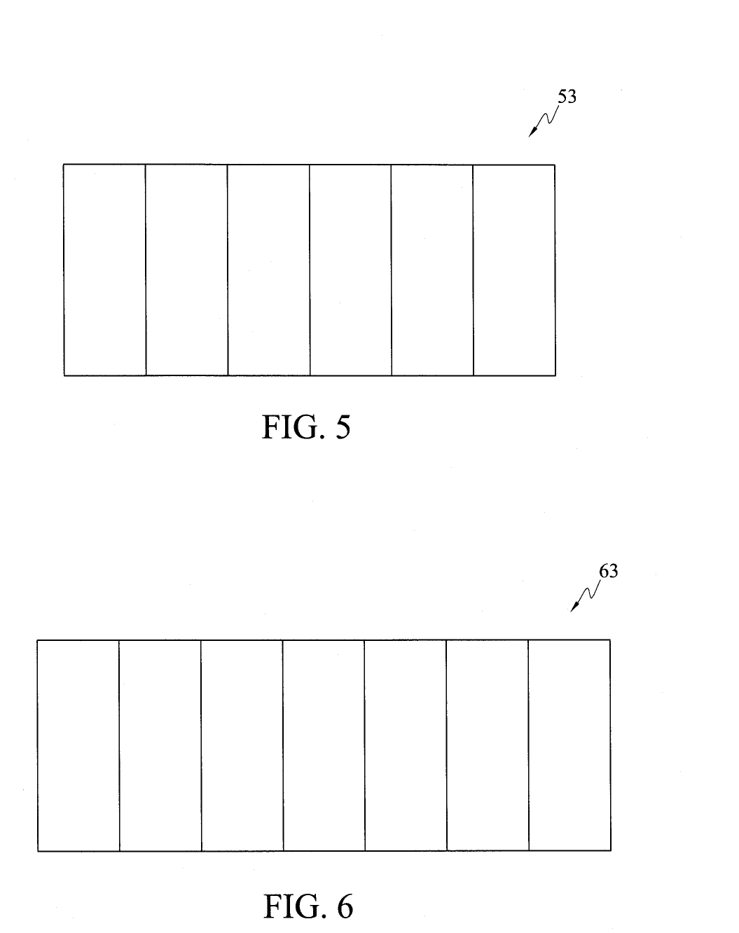

In other embodiments, referring to FIGS. 5 and 6, the shielding structure 53, 63 has six or seven shielding layers.

Therefore, the semiconductor package of the present invention has a plurality of shielding layers formed on an outer surface of a packaging structure so as to increase the reflection loss. The shielding structure is similar to a capacitor. When DC or low-frequency electromagnetic interference occurs, the impedance of the capacitor is infinite. Therefore, the present invention can greatly attenuate electromagnetic waves, reduce the cost and effectively control the overall thickness of the semiconductor package.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A semiconductor package, comprising:
a packaging structure having at least a semiconductor element; and
a shielding structure comprising at least three shielding layers sequentially stacked on the packaging structure so as to cover the semiconductor element, wherein a middle layer of the shielding layers is lower in electrical conductivity than adjacent shielding layers on both sides of the middle layer.

2. The package of claim 1, wherein at least two of the shielding layers are made of different materials.

3. The package of claim 1, wherein the shielding layers are made of materials different from one another.

4. The package of claim 1, wherein at least one of the shielding layers is a conductor layer.

5. The package of claim 1, wherein each of the shielding layers is a conductor layer or a non-conductor layer, and at least one of the shielding layers is a conductor layer.

6. The package of claim 1, wherein an encapsulant is formed on the packaging structure in a manner that the semiconductor element is encapsulated by the encapsulant and the shielding structure is formed on the encapsulant.

7. The package of claim 1, wherein the shielding structure has three shielding layers.

8. The package of claim 1, wherein the shielding structure has four shielding layers.

9. The package of claim 1, wherein the shielding structure has five shielding layers.

10. The package of claim 1, wherein the shielding structure has six shielding layers.

11. The package of claim 1, wherein the shielding structure has seven shielding layers.
